(19) United States
(12) Patent Application Publication
(10) Pub. No.: US 2026/0361279 A1
(43) Pub. Date: Nov. 12, 2026

(54) METHOD AND DEVICE FOR SUPPLYING HIGH OUTPUT RF POWER

(71) Applicant: DAWONMEDAX,. LTD., Ansan-si Gyeonggi-do (KR)

(72) Inventors: Jae Eun HAN, Siheung-si, Gyeonggi-do (KR); Woong Hee KIM, Incheon (KR); Hyeon jin SEO, Seoul (KR); Hyo Jin KIM, Siheung-si, Gyeonggi-do (KR); Hyoung Jin YUN, Siheung-si, Gyeonggi-do (KR); Dong Su KIM, Siheung-si, Gyeonggi-do (KR); Young Soon BAE, Incheon (KR); Sun Soon PARK, Suwon-si, Gyeonggi-do (KR)

(73) Assignee: DAWONMEDAX,. LTD., Ansan-si Gyeonggi-do (KR)

(21) Appl. No.: 19/477,038

(22) PCT Filed: Apr. 26, 2023
(86) PCT No.: PCT/KR2023/005667

§ 371 Date: Oct. 20, 2025

(30) Foreign Application Priority Data
Apr. 20, 2023 (KR) 10-2023-0051767

(51) Int. Cl. H03F 3/24

(52) U.S. Cl. CPC H03F 3/245; H03F 2200/451

(57) ABSTRACT

A method and device for supplying high output radio frequency (RF) power are disclosed. According to an embodiment of the present disclosure, a device for supplying high output RF power may comprise a low level radio frequency (LLRF) module that supplies a first RF power to a first power amplifier, the first power amplifier that generates a second RF power by amplifying the first RF power, and supplies the second RF power to a second power amplifier, a modulator that supplies high voltage pulses to the second power amplifier, and the second power amplifier that generates a third RF power by using the second RF power and the high voltage pulses.

### CROSS-REFERENCE TO RELATED APPLICATION

This application claims priority to Korean Patent Application No. 10-2023-0051767, filed on Apr. 20, 2023, the entire contents of which are incorporated herein by reference.

### TECHNICAL FIELD

The present invention relates to a method and device for supplying high output radio frequency (RF) power. More specifically, the present invention relates to a method and device for supplying high output RF power by supplying power and voltage to a klystron amplifier and performing feedforward control to control a phase and amplitude of the RF power.

### BACKGROUND OF THE INVENTION

The content described below merely provides background information related to the present embodiment, and does not constitute the prior art.

Radio Frequency (RF) refers to a frequency used for wireless communication applications by means of radio waves. The radio frequency may correspond to a frequency having a vibration frequency between 3 kHz and 3 THz. The high output RF power is used in an RF linear accelerating tube. An RF power amplifier may be used to generate the high output RF power. The RF power amplifier corresponds to an electronic amplifier that converts a low-power radio frequency signal into a high-power radio frequency signal. There are mainly two types of power control methods for the RF power amplifier.

One is a power control method based on closed-loop control. The power control method based on the closed-loop control is a method of controlling mainly input power of the RF power amplifier to control final output power. The other is a power control method based on open-loop control. The power control method based on the open-loop control is a method of controlling mainly voltage to control final output power. When the RF power amplifier is used to generate high output RF power required in the RF linear accelerating tube, the high output RF power generated by using the RF power amplifier should be greater than or equal to a certain magnitude, and a phase and amplitude of the RF power should have stability.

### SUMMARY OF THE INVENTION

### Technical Problem

The present disclosure may amplify radio frequency (RF) power by using a Klystron amplifier.

In addition, according to an embodiment, stability of high output RF power may be improved by using feedforward control.

Further, according to an embodiment, stability of an amplitude and a phase of the high output RF power may be improved.

The problems to be solved by the present invention are not limited to the above-mentioned problems, and other problems that are not mentioned will be clearly understood by those skilled in the art from the following description.

### Solution to Problem

According to the present disclosure, a device for supplying high output RF power may comprise: a low level radio frequency (LLRF) module that supplies a first RF power to a first power amplifier; the first power amplifier that generates a second RF power by amplifying the first RF power, and supplies the second RF power to a second power amplifier; a modulator that supplies high voltage pulses to the second power amplifier, and the second power amplifier that generates a third RF power by using the second RF power and the high voltage pulses.

According to the present disclosure, a method performed by a device for supplying high output RF power may comprise: supplying a first RF power to a first power amplifier; amplifying the first RF power to generate a second RF power; supplying the second RF power to a second power amplifier; supplying high voltage pulses to the second power amplifier, and generating a third RF power by using the second RF power and the high voltage pulses.

According to the present disclosure, a computer program, coupled with a computing device that is hardware, may be stored in a computer-readable recording medium to cause the computing device to execute: supplying a first RF power to a first power amplifier; amplifying the first RF power to generate a second RF power, supplying the second RF power to a second power amplifier, supplying high voltage pulses to the second power amplifier, and generating a third RF power by using the second RF power and the high voltage pulses.

According to the present disclosure, a computer-readable recording medium may have stored thereon instructions which, when executed by a computer, cause the computer to execute: supplying a first RF power to a first power amplifier; amplifying the first RF power to generate a second RF power; supplying the second RF power to a second power amplifier; supplying high voltage pulses to the second power amplifier; and generating a third RF power by using the second RF power and the high voltage pulses.

### Effects of the Invention

According to the present disclosure, there is an effect of amplifying radio frequency (RF) power by using a Klystron amplifier.

In addition, according to an embodiment, there is an effect of improving stability of the high output RF power by using the feedforward control.

Further, according to an embodiment, there is an effect of improving stability of amplitude and phase of the high output RF power.

The effects obtainable from the present disclosure are not limited to the above-mentioned effects, and other effects that are not mentioned will be clearly understood by those skilled in the art from the following description.

### BRIEF DESCRIPTION OF THE DRAWINGS

FIG. 1 is a block diagram for describing a device for supplying high output radio frequency (RF) power according to an embodiment of the present disclosure.

FIG. 2 is a diagram for describing an RF linear accelerating tube and a device for supplying high output RF power, according to an embodiment of the present disclosure.

FIG. 3 is a diagram for describing a modulator and a Klystron amplifier, according to an embodiment of the present disclosure.

FIG. 4 is a diagram for describing a voltage supplied by a modulator according to an embodiment of the present disclosure.

FIGS. 5A and 5B are each a diagram for describing an amplitude of high output RF power and a phase of high output RF power, according to an embodiment of the present disclosure.

FIGS. 6A and 6B are each a diagram for describing an amplitude of high output RF power and a phase of high output RF power, according to another embodiment of the present disclosure.

FIG. 7 is a diagram for describing a method for supplying high output RF power according to an embodiment of the present disclosure.

### DETAILED DESCRIPTION OF THE INVENTION

Hereinafter, some exemplary embodiments of the present disclosure will be described in detail with reference to the accompanying drawings. In the following description, like reference numerals preferably designate like elements, although the elements are shown in different drawings. Further, in the following description of some embodiments, a detailed description of known functions and configurations incorporated therein will be omitted for the purpose of clarity and for brevity.

Additionally, various terms such as first, second, A, B, (a), (b), etc., are used solely to differentiate one component from the other but not to imply or suggest the substances, order, or sequence of the components. Throughout this specification, when a part ‘includes’ or ‘comprises’ a component, the part is meant to further include other components, not to exclude thereof unless specifically stated to the contrary. The terms such as ‘unit’, ‘module’, and the like refer to one or more units for processing at least one function or operation, which may be implemented by hardware, software, or a combination thereof.

The following detailed description, together with the accompanying drawings, is intended to describe exemplary embodiments of the present disclosure and is not intended to represent the only embodiments in which the present disclosure may be practiced.

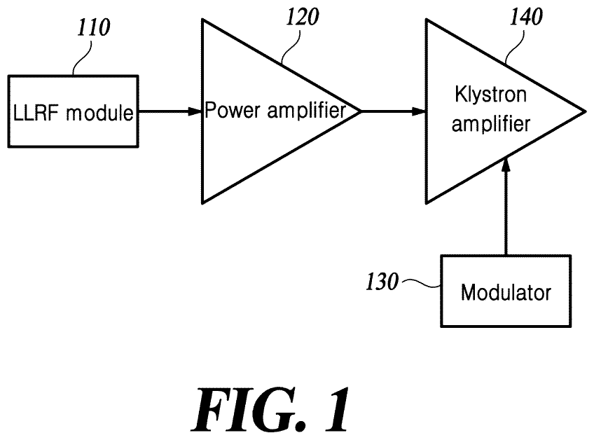

FIG. 1 is a block diagram for describing a device for supplying high output radio frequency (RF) power according to an embodiment of the present disclosure. In order to operate an RF linear accelerating tube, high output RF power is required. As an example, a peak value of the high output RF power may correspond to 1.5 MW, and an average value of the high output RF power may correspond to 150 kW. Here, a duty ratio of the high output RF power may correspond to 10%. As an example, a pulse length of the high output RF power may correspond to 800 microsecs, and a repetition rate of the high output RF power may correspond to 120 Hz. As an example, an amplitude of the high output RF power may require stability within +/−1%. As an example, a phase of the high output RF power may require stability within +/−1 degree.

Referring to FIG. 1, the device for supplying high output RF power may include a low level radio frequency (LLRF) module 110, a power amplifier 120, a modulator 130, and a Klystron amplifier 140. The device for supplying high output RF power of the present disclosure may supply RF power required in the RF linear accelerating tube. The LLRF module 110 may supply predetermined RF power to the power amplifier 120. As an example, the LLRF module 110 may supply several mW of power to the power amplifier 120. Feedforward control may be performed by using the LLRF module 110. The feedforward control may be performed by changing a phase of the RF power or an amplitude of the RF power supplied by the LLRF module 110 to the power amplifier 120. The feedforward control may improve stability of the RF power supplied from the device for supplying high output RF power. The power amplifier 120 may correspond to a solid state power amplifier (SSPA). The SSPA may correspond to a power amplifier made by using a solid state semiconductor. The SSPA may be made by using a solid state physical element rather than a vacuum tube.

The power amplifier 120 may amplify the RF power supplied from the LLRF module 110. The power amplifier 120 may supply the amplified RF power to the Klystron amplifier 140. As an example, the power amplifier 120 may receive and amplify several mW of RF power from the LLRF module 110, and supply 100 W of power to the Klystron amplifier 140. The modulator 130 may supply high voltage pulses to the Klystron amplifier 140. As an example, the modulator 130 may supply a pulse voltage of 90 kV to the Klystron amplifier 140. The modulator 130 may use a high voltage switch and a high voltage capacitor to supply voltage to the Klystron amplifier 140. A voltage droop may occur in the voltage formed in the modulator 130. As an example, a voltage drop of 5% may occur.

The Klystron amplifier 140 may generate high output RF power by using the RF power supplied from the power amplifier 120 and the voltage supplied from the modulator 130. The Klystron amplifier 140 may obtain an input and an output by using a high-performance resonator, and thus may have superior frequency stability compared to other amplifiers. As an example, the Klystron amplifier 140 may use a frequency of about 200 MHz to 100 GHz. The Klystron amplifier 140 may include two resonators. In the Klystron amplifier 140, when an electron beam passes through a first resonator, bunching of electrons may occur and a standing wave may be generated. An electron flow entering the first resonator may repeat acceleration and deceleration. A standing wave electric field may cause the electron flow to bunch at a specific position. When the bunching of electrons enters a second resonator, a strong standing wave may be formed again. The standing wave may output the amplified RF power to the outside by using a combiner.

The Klystron amplifier 140 may correspond to an RF amplifier. A gain of the Klystron amplifier 140 may correspond to 50 dB. An efficiency of the Klystron amplifier 140 may correspond to 60%. As an example, the Klystron amplifier 140 may generate RF power of 1.5 MW. A portion of the RF power may be signal-processed by coupling out the high output RF power output from the Klystron amplifier 140. The stability of a phase of the high output RF power and stability of an amplitude of the high output RF power may be measured by using the the signal-processed portion of the RF power.

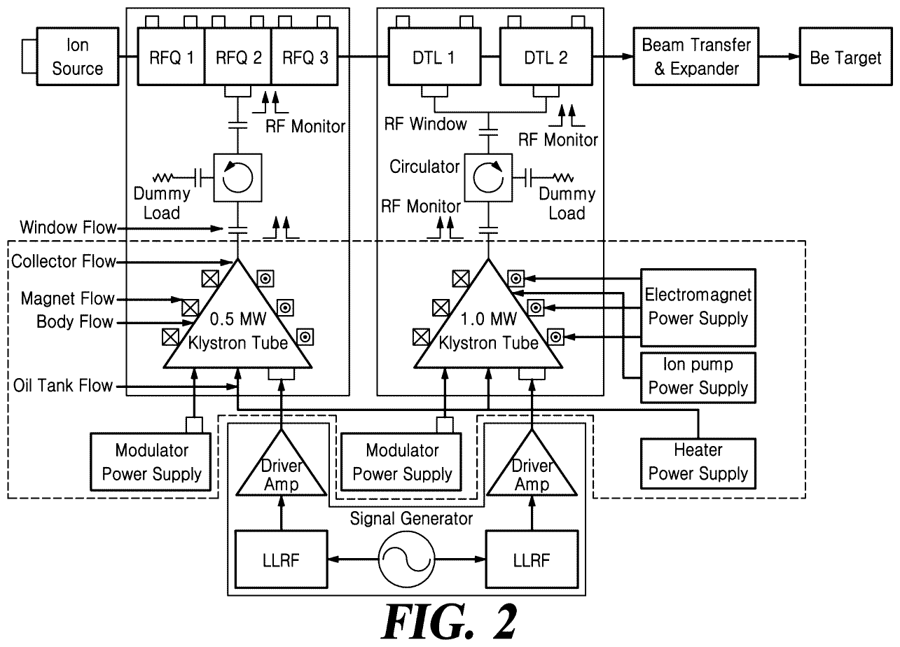

FIG. 2 is a diagram for describing an RF linear accelerating tube and a device for supplying high output RF power, according to an embodiment of the present disclosure. The RF linear accelerating tube is a device that applies energy to charged particles moving linearly by using an RF electromagnetic field, thereby accelerating the charged particles. The RF linear accelerating tube varies in size from several tens of kilometers to several tens of centimeters, and is widely used for industrial, medical, research, military purposes, and the like. High output RF power is required to operate the RF linear accelerating tube. As an example, a proton beam may be accelerated to 10 MeV by using the RF linear accelerating tube. In this case, the peak amplitude of the required high output RF power may correspond to 1.5 MW.

Referring to FIG. 2, two modulators may supply high voltage pulses to two Klystron amplifiers. Two LLRF modules may supply a small amount of RF power to two power amplifiers (Driver Amps). The two power amplifiers (Driver Amps) may amplify the small amount of RF power supplied from the two LLRF modules. The two power amplifiers (Driver Amps) may supply the amplified RF power to the two Klystron amplifiers. The two Klystron amplifiers may generate high output RF power by using the supplied RF power and the supplied high voltage pulses. The feedforward control may be performed by using the two LLRF modules. Accordingly, the stability of the high output RF power generated from the two Klystron amplifiers may be improved.

One Klystron amplifier may supply the high output RF power to one radio frequency quadrupole (RFQ) linear accelerating tube divided into three parts. The other Klystron amplifier may supply the high output RF power to one drift tube linear (DTL) accelerating tube divided into two parts. The RFQ linear accelerating tube and the DTL linear accelerating tube may accelerate charged particles by using the supplied high output RF power, respectively.

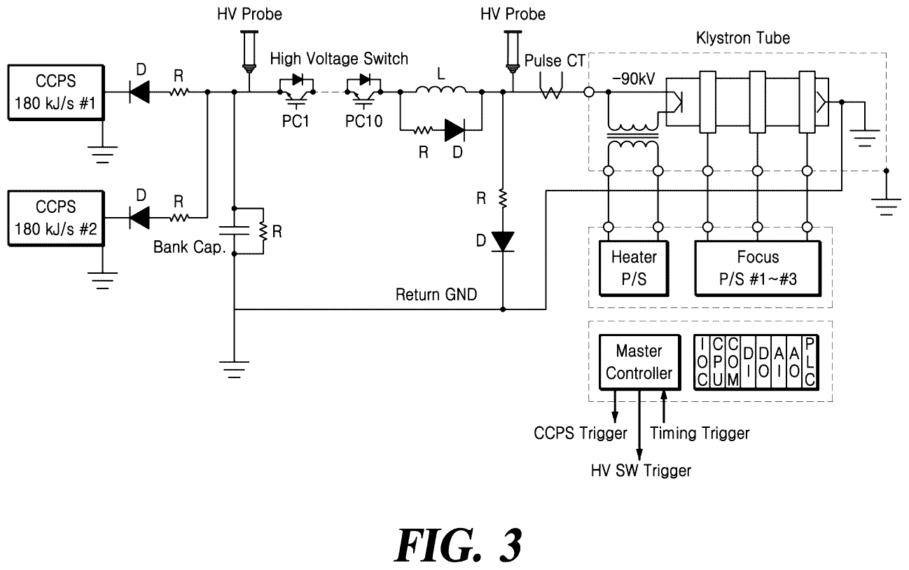

FIG. 3 is a diagram for describing a modulator and a Klystron amplifier, according to an embodiment of the present disclosure.

Referring to FIG. 3, the modulator may include two capacitor charging power supplies (CCPSs), a capacitor bank, a high voltage switch, and the like. A high voltage may be generated in the CCPS. A pulse may be formed by using the capacitor bank and the high voltage switch. The capacitor bank and the high voltage switch may be formed in a loop shape, thereby generating the pulses. The generated high voltage pulses may be supplied to the Klystron amplifier. The voltage droop may occur in the high voltage pulses due to a resistor, an inductor, and a capacitor present in the modulator.

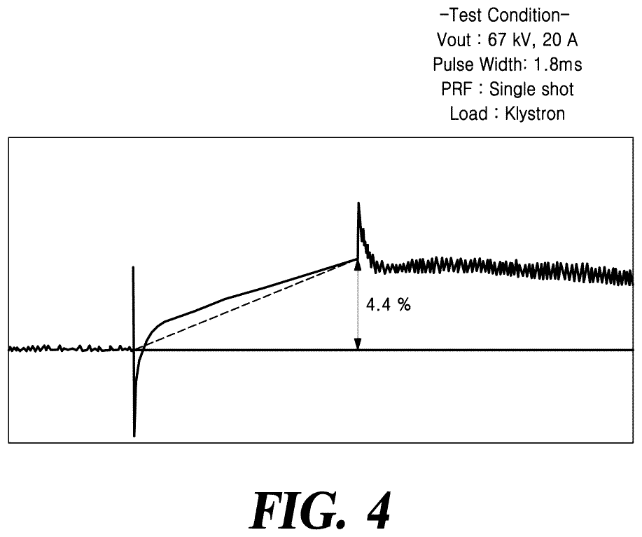

FIG. 4 is a diagram for describing a voltage supplied by a modulator, according to an embodiment of the present disclosure.

Referring to FIG. 4, the voltage droop may occur in the high voltage pulses supplied from the modulator to the Klystron amplifier. As an example, when an output voltage is 67 kV, a pulse width is 1.8 ms, and a load is the Klystron amplifier in the high voltage pulses generated by the modulator, the voltage droop may occur at 3 kV. The voltage droop ratio may correspond to 4.4% relative to the output voltage.

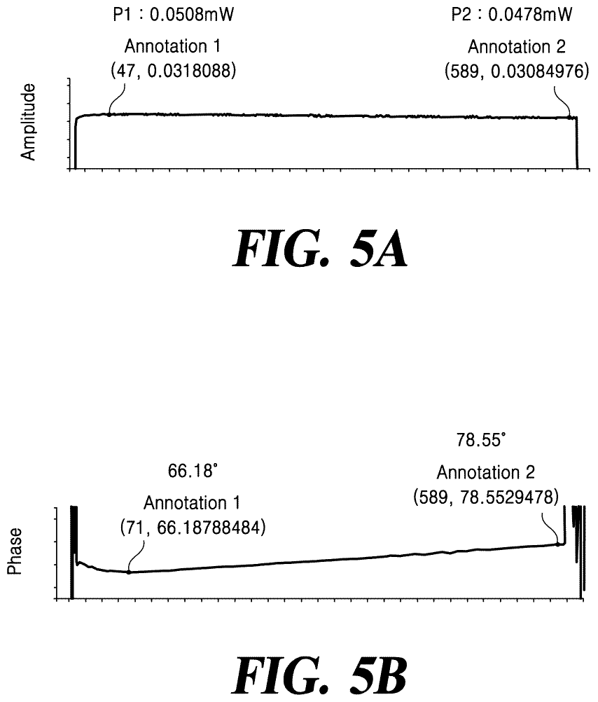

FIGS. 5A and 5B are each a diagram for describing an amplitude of high output RF power and a phase of high output RF power, according to an embodiment of the present disclosure.

Referring to FIG. 5A, the Klystron amplifier may output high output RF power without feedforward control using the LLRF module. A portion of the RF power may be signal-processed by coupling out the high output RF power. An amplitude of the signal-processed portion of the RF power may be measured. A maximum amplitude of the signal-processed portion of the RF power may correspond to 0.0508 mW, and a minimum amplitude thereof may correspond to 0.0478 mW. Accordingly, stability of the amplitude of the high output RF power may correspond to +/−3%.

Referring to FIG. 5B, the Klystron amplifier may output high output RF power without feedforward control using the LLRF module. A portion of the RF power may be signal-processed by coupling out the high output RF power. A phase of the signal-processed portion of the RF power may be measured. A maximum phase of the signal-processed portion of the RF power may correspond to 78.55 degrees, and a minimum phase thereof may correspond to 66.18 degrees. Accordingly, stability of the phase of the high output RF power may correspond to +/−6 degrees.

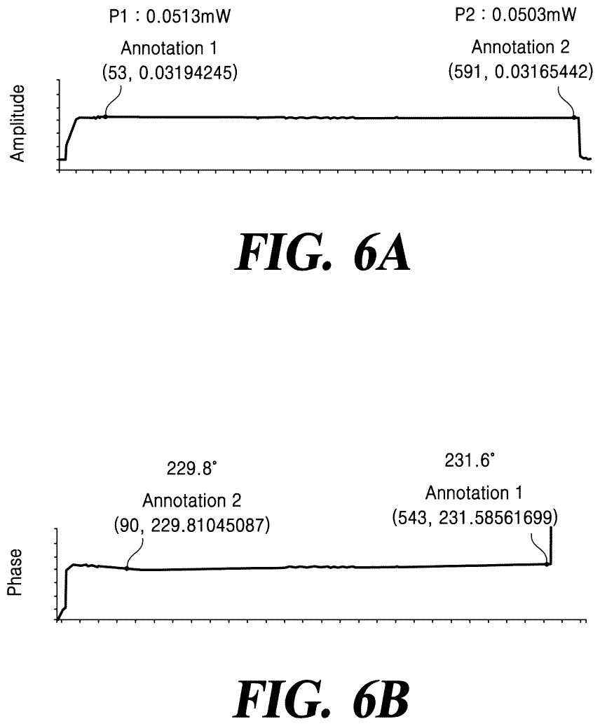

FIGS. 6A and 6B are each a diagram for describing an amplitude of high output RF power and a phase of high output RF power, according to another embodiment of the present disclosure.

Referring to FIG. 6A, the Klystron amplifier may output high output RF power by performing feedforward control using the LLRF module. A portion of the RF power may be signal-processed by coupling out the high output RF power. An amplitude of the signal-processed portion of the RF power may be measured. A maximum amplitude of the signal-processed portion of the RF power may correspond to 0.0513 mW, and a minimum amplitude thereof may correspond to 0.0503 mW. Accordingly, stability of the amplitude of the high output RF power may correspond to +/−0.9%.

Referring to FIG. 6B, the Klystron amplifier may output high output RF power by performing feedforward control using the LLRF module. A portion of the RF power may be signal-processed by coupling out the high output RF power. A phase of the signal-processed portion of the RF power may be measured. A maximum phase of the signal-processed portion of the RF power may correspond to 231.6 degrees, and a minimum phase thereof may correspond to 229.8 degrees. Accordingly, stability of the phase of the high output RF power may correspond to +/−0.5 degrees.

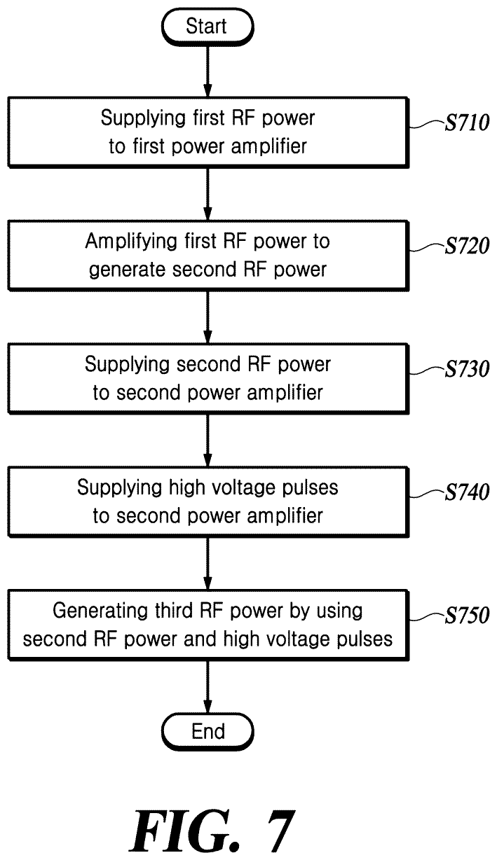

FIG. 7 is a diagram for describing a method for supplying high output RF power according to an embodiment of the present disclosure.

Referring to FIG. 7, a device for supplying high output RF power may supply a first RF power to a first power amplifier (S710). The device for supplying high output RF power may amplify the first RF power to generate a second RF power (S720). The device for supplying high output RF power may supply the second RF power to a second power amplifier (S730). The device for supplying high output RF power may supply high voltage pulses to the second power amplifier (S740). The device for supplying high output RF power may generate a third RF power by using the second RF power and the high voltaged pulse (S750). The first power amplifier may correspond to an SSPA. The second power amplifier may correspond the Klystron amplifier. The device for supplying high output RF power may supply a fourth RF power to the first power amplifier based on at least one of an amplitude of the third RF power and a phase of the third RF power. The high voltage pulses may be generated by using a capacitor bank and a high voltage switch in a modulator. Stability of the amplitude of the third RF power and stability of the phase of the third RF power may be measured by signal-processing the third RF power. The amplitude of the third RF power and the phase of the third RF power may be maintained within a predetermined range by the fourth RF power.

Each element of the apparatus or method in accordance with the present disclosure may be implemented in hardware or software, or a combination of hardware and software. The functions of the respective elements may be implemented in software, and a microprocessor may be implemented to execute the software functions corresponding to the respective elements.

Various embodiments of systems and techniques described herein can be realized with digital electronic circuits, integrated circuits, field programmable gate arrays (FPGAs), application specific integrated circuits (ASICs), computer hardware, firmware, software, and/or combinations thereof. The various embodiments can include implementation with one or more computer programs that are executable on a programmable system. The programmable system includes at least one programmable processor, which may be a special purpose processor or a general purpose processor, coupled to receive and transmit data and instructions from and to a storage system, at least one input device, and at least one output device. Computer programs (also known as programs, software, software applications, or code) include instructions for a programmable processor and are stored in a “computer-readable recording medium.”

The computer-readable recording medium may include all types of storage devices on which computer-readable data can be stored. The computer-readable recording medium may be a non-volatile or non-transitory medium such as a read-only memory (ROM), a random access memory (RAM), a compact disc ROM (CD-ROM), magnetic tape, a floppy disk, or an optical data storage device. In addition, the computer-readable recording medium may further include a transitory medium such as a data transmission medium. Furthermore, the computer-readable recording medium may be distributed over computer systems connected through a network, and computer-readable program code can be stored and executed in a distributive manner.

Although operations are illustrated in the flowcharts/timing charts in this specification as being sequentially performed, this is merely an exemplary description of the technical idea of one embodiment of the present disclosure. In other words, those skilled in the art to which one embodiment of the present disclosure belongs may appreciate that various modifications and changes can be made without departing from essential features of an embodiment of the present disclosure, that is, the sequence illustrated in the flowcharts/timing charts can be changed and one or more operations of the operations can be performed in parallel. Thus, flowcharts/timing charts are not limited to the temporal order.

Although exemplary embodiments of the present disclosure have been described for illustrative purposes, those skilled in the art will appreciate that various modifications, additions, and substitutions are possible, without departing from the idea and scope of the claimed invention. Therefore, exemplary embodiments of the present disclosure have been described for the sake of brevity and clarity. The scope of the technical idea of the present embodiments is not limited by the illustrations. Accordingly, one of ordinary skill would understand that the scope of the claimed invention is not to be limited by the above explicitly described embodiments but by the claims and equivalents thereof.

1. A device for supplying high output RF power, comprising:
a low level radio frequency (LLRF) module that supplies a first RF power to a first power amplifier;
the first power amplifier that generates a second RF power by amplifying the first RF power, and supplies the second RF power to a second power amplifier;
a modulator that supplies high voltage pulses to the second power amplifier; and
the second power amplifier that generates a third RF power by using the second RF power and the high voltage pulses.

2. The device of claim 1, wherein the first power amplifier corresponds to a solid state power amplifier (SSPA).

3. The device of claim 1, wherein the second power amplifier corresponds to a Klystron amplifier.

4. The device of claim 1, wherein the LLRF module is configured to supply a fourth RF power to the first power amplifier based on at least one of an amplitude of the third RF power and a phase of the third RF power.

5. The device of claim 1, wherein the modulator is configured to generate the high voltage pulses by using a capacitor bank and a high voltage switch.

6. The device of claim 4, wherein stability of the amplitude of the third RF power and stability of the phase of the third RF power are measured by signal-processing the third RF power.

7. The device of claim 4, wherein the amplitude of the third RF power and the phase of the third RF power are maintained within a predetermined range by the fourth RF power.

8. A method performed by a device for supplying high output RF power, the method comprising:
supplying a first RF power to a first power amplifier;
amplifying the first RF power to generate a second RF power;
supplying the second RF power to a second power amplifier;
supplying high voltage pulses to the second power amplifier; and
generating a third RF power by using the second RF power and the high voltage pulses.

9. The method of claim 8, wherein the first power amplifier corresponds to a solid state power amplifier (SSPA).

10. The method of claim 8, wherein the second power amplifier corresponds to a Klystron amplifier.

11. The method of claim 8, further comprising:
supplying a fourth RF power to the first power amplifier based on at least one of an amplitude of the third RF power and a phase of the third RF power.

12. The method of claim 8, wherein the high voltage pulses are generated in a modulator by using a capacitor bank and a high voltage switch.

13. The method of claim 11, wherein stability of the amplitude of the third RF power and stability of the phase of the third RF power are measured by signal-processing the third RF power.

14. The method of claim 11, wherein the amplitude of the third RF power and the phase of the third RF power are maintained within a predetermined range by the fourth RF power.

15. (canceled)

16. A non-transitory computer-readable recording medium having stored thereon instructions which, when executed by a computer, cause the computer to execute:
supplying a first RF power to a first power amplifier;
amplifying the first RF power to generate a second RF power;
supplying the second RF power to a second power amplifier;
supplying high voltage pulses to the second power amplifier; and
generating a third RF power by using the second RF power and the high voltage pulses.
